(19) United States
(12) Patent Application Publication
(10) Pub. No.: US 2026/0013202 A1
(43) Pub. Date: Jan. 8, 2026

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventors: Akira TAMENORI, Matsumoto-city (JP); Takaaki SUZAWA, Matsumoto-city (JP); Shunsuke TANAKA, Matsumoto-city (JP); Kohichi HASHIMOTO, Matsumoto-city (JP)

(73) Assignee: FUJI ELECTRIC CO., LTD., Kawasaki-shi (JP)

(21) Appl. No.: 19/223,341

(22) Filed: May 30, 2025

(30) Foreign Application Priority Data
Jul. 8, 2024 (JP) 2024-109909

(51) Int. Cl. H10D 64/62; H10D 30/01; H10D 30/66; H10D 62/10; H10D 62/832; H10D 64/01

(52) U.S. Cl. CPC H10D 64/62; H10D 30/0291; H10D 30/668; H10D 62/109; H10D 62/8325; H10D 64/01

(57) ABSTRACT

A semiconductor device, including: a semiconductor substrate; an element structure disposed on the semiconductor substrate; and a main electrode disposed on the element structure, wherein the main electrode is a film containing Al, in which an area having Al orientation of (111) occupies 99% or more.

### CROSS REFERENCE TO RELATED APPLICATIONS

This application is based upon and claims the benefit of priority of the prior Japanese Patent Application No. 2024-109909, filed on Jul. 8, 2024, the entire contents of which are incorporated herein by reference.

### BACKGROUND OF THE INVENTION

### 1. Field of the Invention

Embodiments of the invention relate to a semiconductor device and a method of manufacturing a semiconductor device.

### 2. Description of the Related Art

Conventionally, a technique has been proposed in which an Al film and a Si substrate are sintered at a temperature of, for example, 420 degrees C. for 60 minutes to make the entire surface of the Al film a homogeneous (111) surface (refer to, for example, Japanese Laid-Open Patent Publication No. 2011-77203). A technique has also been proposed in which an Al alloy layer is disposed and then a barrier metal layer is disposed on the Al alloy layer so that the Al alloy layer on the barrier metal layer is oriented in the (111) surface to be made dense (refer to, for example, Japanese Laid-Open Patent Publication No. 2021-77729). A technique has also been proposed in which aluminum is formed as warm aluminum (about 350 degrees C. to 450 degrees C.) by sputtering (refer to, for example, Japanese Laid-Open Patent Publication No. 2009-21635).

### SUMMARY OF THE INVENTION

According to an embodiment of the present disclosure, a semiconductor device includes: a semiconductor substrate; an element structure disposed on the semiconductor substrate; and a main electrode disposed on the element structure. The main electrode is a film containing Al, in which an area having Al orientation of (111) occupies 99% or more of a total area of the film containing Al.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting an active structure of a silicon carbide semiconductor device according to an embodiment.

FIG. 2 is a flowchart of a method of manufacturing the silicon carbide semiconductor device according to the embodiment.

FIG. 3 is a cross-sectional view depicting sputtering of an Al—Si film of the silicon carbide semiconductor device according to the embodiment.

FIG. 4 is a graph depicting an orientation ratio of the Al—Si film in a conventional example and first and second examples.

FIG. 5 is a cross-sectional view depicting a normal Al—Si film and a plating film of a conventional semiconductor device.

FIG. 6 is a cross-sectional view depicting an Al—Si film and a plating film in which many etch pits occur in the conventional semiconductor device.

FIG. 7 is a cross-sectional view depicting an Al—Si film and a plating film in which etch pits are connected to each other in the conventional semiconductor device.

### DETAILED DESCRIPTION OF THE INVENTION

First, problems associated with the conventional techniques are discussed. In the conventional semiconductor devices, there is a problem of excessive formation of etch pits on a surface of an aluminum (Al) or aluminum-silicon (Al—Si) film of a surface electrode, causing a defect in which a plating film peels off from a top layer of the Al film or Al—Si film.

An outline of an embodiment of the present disclosure is described. A semiconductor device according to the present disclosure, solving the problems above, and achieving an object has the following features. The semiconductor device has a first-conductivity-type semiconductor substrate; an element structure disposed on the semiconductor substrate; and a main electrode disposed on the element structure. The main electrode is an Al alloy film, and an area of the Al alloy film where Al orientation is (111) is 99% or more.

According to the above disclosure, an area of an Al—Si film (Al alloy film) where the Al orientation is (111) occupies 99% or more. Thus, generation of abnormal etch pits during plating pre-treatment is suppressed and the etch pits can be prevented from becoming connected to each other in the Al—Si film after plating deposition. Thus, mechanical strength after chip assembly can be improved to ensure product reliability.

Further, in the semiconductor device according to the present disclosure, the Al alloy film has an average particle diameter of 5.5 μm or more but not more than 10 μm.

In the semiconductor device according to the present disclosure, the Al alloy film is an Al film, the Al—Si film, or an Al—Si—Cu film.

A method of manufacturing a semiconductor device according to the present disclosure, solving the problems above, and achieving an object has the following features. First, a first step of forming an element structure on a first-conductivity-type semiconductor substrate is performed. Then, a second step of forming a main electrode on the element structure is performed. In the second step, the main electrode is formed of the Al alloy film, the Al alloy film is deposited by a sputtering method, and the wafer temperature during deposition is 350 degrees C. or more but not more than 480 degrees C.

Further, in the method of manufacturing a semiconductor device according to the present disclosure, in the sputtering, an electrostatic chuck function is turned off when the Al alloy film is deposited by the sputtering method.

Findings underlying the present disclosure are discussed. Here, problems of the conventional semiconductor devices are described. In some cases, in the conventional semiconductor devices, an Al—Si film of a surface electrode is formed by sputtering, electroless Ni plating and Au plating are performed on the Al—Si film, and assembly is performed by soldering a surface side of the device.

In this case, during a plating treatment, the Al—Si film surface must be the pre-treated in an etching bath or a zincate treatment bath in order to remove an aluminum oxidation film and allow zinc (Zn) or iron (Fe) ions, which serve as catalysts, to attach to the Al—Si film surface. In the pre-treatment, the Al—Si film is etched about 0.2 to 0.5 μm and thinned.

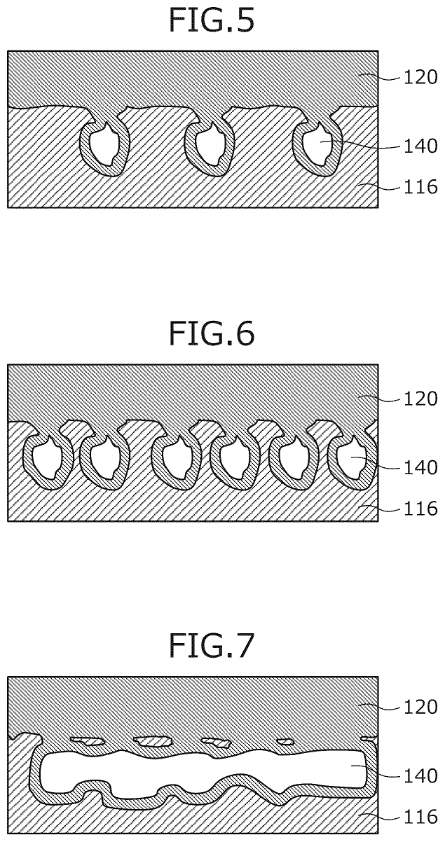

Here, the Al—Si film is polycrystalline and characteristics of the Al orientation vary depending on sputtering conditions. FIG. 5 is a cross-sectional view depicting a normal Al—Si film and a plating film of a conventional semiconductor device. In a case that orientation of an Al—Si film 116 is (111), etch pits 140 caused by the pre-treatment for plating occur sporadically, but do not grow to the extent that the etch pits 140 are connected to each other and thus, cause no problems with the strength of a plating film 120 on the Al—Si film 116.

FIG. 6 is a cross-sectional view depicting an Al—Si film and a plating film in which many etch pits occur in the conventional semiconductor device. In a case where the orientation of the Al—Si film 116 deviates from (111), etching of aluminum progresses excessively to form the etch pits 140 caused by the plating pre-treatment.

FIG. 7 is a cross-sectional view depicting an Al—Si film and a plating film in which etch pits are connected to each other in the conventional semiconductor device. When the extent of formation of the etch pits 140 further worsens, a problem occurs in that the etch pits 140 adjacent to each other are connected inside the Al—Si film 116. Since a cavity is formed between the Al—Si film 116 and the plating film 120, when such an Al—Si film 116 is plated, the mechanical strength of an Al—Si film 116 surface cannot be maintained, resulting in a problem that the plating film 120 peels off from the top layer of the Al—Si film 116 after the assembly process.

Embodiments of a semiconductor device and a method of manufacturing a semiconductor device according to the present disclosure are described in detail with reference to the accompanying drawings. In the present description and accompanying drawings, layers and regions prefixed with n or p mean that majority carriers are electrons or holes. Additionally, + or − appended to n or p means that the dopant concentration is higher or lower, respectively, than layers and regions without + or −. In the description of the embodiments below and the accompanying drawings, main portions that are identical are given the same reference numerals and are not repeatedly described. Further, with consideration of variation in manufacturing, description indicating the same or equal may be within 5%.

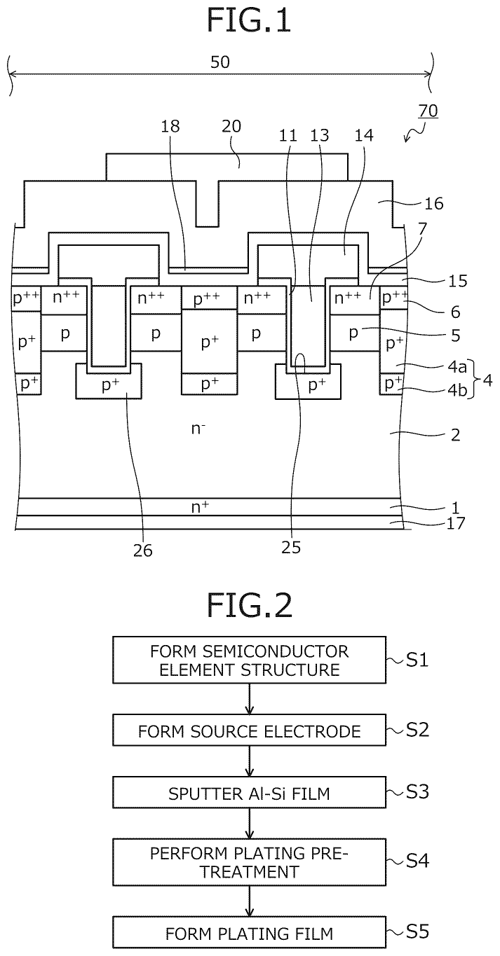

A semiconductor device according to the present disclosure is configured using a wide band gap semiconductor. In the embodiment, a silicon carbide semiconductor device fabricated using, for example, silicon carbide (SiC) as the wide band gap semiconductor is described using an insulated gate type metal oxide semiconductor field effect transistor (MOSFET) as an example. FIG. 1 is a cross-sectional view depicting an active structure of the silicon carbide semiconductor device according to the embodiment.

A silicon carbide semiconductor device 70 according to the embodiment has a semiconductor substrate (hereinafter referred to as a silicon carbide substrate (semiconductor substrate (semiconductor chip))) containing silicon carbide and having an active region 50 and an edge termination region (not depicted) surrounding a periphery of the active region 50 in. The active region 50 is a region through which a current flows when the device is in an on-state. The edge termination region is a region that relaxes an electric field of a front side of a drift region of the substrate and maintains a breakdown voltage.

As depicted in FIG. 1, the silicon carbide substrate has an n⁻-type drift region 2 containing silicon carbide on a front surface of an n⁺-type support substrate (an n⁺-type silicon carbide substrate, a first-conductivity-type semiconductor substrate) 1 containing silicon carbide, and a p-type base region 5 containing silicon carbide on a first surface of the n⁻-type drift region 2 opposite to a second surface thereof facing the n⁺-type silicon carbide substrate 1. The n⁺-type silicon carbide substrate 1 functions as a drain region. For example, a buffer layer or the like that reduces growth of crystal defects from the n⁺-type silicon carbide substrate 1 may be provided between the n⁻-type drift region 2 and the n⁺-type silicon carbide substrate 1.

The n⁺-type silicon carbide substrate 1 is a silicon carbide single crystal substrate. A dopant concentration of the n⁻-type drift region 2 is lower than a dopant concentration of the n⁺-type silicon carbide substrate 1. The n⁻-type drift region 2 reaches the p-type base region 5 and is in contact with the p-type base region 5 and later-described p⁺-type partial regions 4; the n⁻-type drift region 2 also reaches later-described trenches 25 in a direction parallel to the front surface of the semiconductor substrate and is in contact with gate insulating films 11. The n⁻-type drift region 2 has, for example, a dopant concentration of not more than 5×10¹⁶ cm⁻³ and a thickness of 5.0 μm or more.

An n-type high concentration region (not depicted) may be provided between the n⁻-type drift region 2 and the p-type base region 5. In a case in which an n-type high concentration region is provided, the n-type high concentration region is in contact with later-described adjacent p⁺-type partial regions 4 and extends in a direction parallel to the front surface of the semiconductor substrate to the trenches 25, where the n-type high concentration region is in contact with the gate insulating films 11. The n-type high concentration region has an upper surface in contact with the p-type base region 5 and a lower surface in contact with the n⁻-type drift region 2. A dopant concentration of the n-type high concentration region is lower than the dopant concentration of the n⁺-type silicon carbide substrate 1 and higher than the dopant concentration of the n⁻-type drift region 2.

A drain electrode 17 constituting a back electrode is disposed on a second main surface (back surface, that is, back surface of the silicon carbide substrate) of the n⁺-type silicon carbide substrate 1. A drain electrode pad (not depicted) is disposed on a front surface of the drain electrode 17.

A trench structure is formed in the silicon carbide substrate, at a first main surface thereof (surface of p-type base region 5). Specifically, the trenches 25 penetrate through the p-type base region 5 from a first surface thereof (the first main surface of the silicon carbide substrate) opposite to a second surface thereof facing the n⁺-type silicon carbide substrate 1, the trenches 25 reaching the n⁻-type drift region 2 (n-type high concentration region in a case where the n-type high concentration region is provided).

The gate insulating films 11 are formed along inner walls of the trenches 25, at bottom and sidewalls of the trenches 25; gate electrodes 13 are formed on the gate insulating films 11 in the trenches 25. The gate electrodes 13 are insulated from the n⁻-type drift region 2 and the p-type base region 5 by the gate insulating films 11. A portion of each of the gate electrodes 13 may protrude from above the trenches 25 (side where a source electrode pad 16 described later is provided) toward the source electrode pad 16.

Upper p⁺-type partial regions 4a are provided in the n⁻-type drift region 2, closer to the first surface thereof opposite to the second surface thereof facing the n⁺-type silicon carbide substrate 1 (the first main surface side of the silicon carbide base). The upper p⁺-type partial regions 4a are provided, for example, between the trenches 25. Lower p⁺-type partial regions 4b in contact with bottoms of the upper p⁺-type partial regions 4a, respectively, are provided in the n⁻-type drift region 2. At the bottoms of the trenches 25, p⁺-type regions 26 are provided respectively. The p⁺-type regions 26 contacting the bottoms of the trenches 25 are provided at positions facing the bottoms of the trenches 25 in the depth direction (direction from the source electrode pad 16 to the back electrode). The p⁺-type partial regions 4 each consists of one of the upper p⁺-type partial regions 4a and one of the lower p⁺-type partial regions 4b between the trenches 25.

A width of each of the p⁺-type regions 26 is equal to or broader than a width of each of the trenches 25. A width of each of the lower p⁺-type partial regions 4b is equal to or broader than a width of each of the upper p⁺-type partial regions 4a. The bottoms of the trenches 25 may reach the p⁺-type regions 26 or may be located in the n⁻-type drift region 2 sandwiched between the p-type base region 5 and the p⁺-type regions 26.

In the p-type base region 5, the n⁺⁺-type source regions 7 and p⁺⁺-type contact regions 6 are selectively disposed in the silicon carbide substrate, at the first main surface thereof. The n⁺⁺-type source regions 7 and the p⁺⁺-type contact regions 6 are in contact with each other.

An interlayer insulating film 14 is disposed in an entire area of the first main surface of the silicon carbide substrate and covers the gate electrodes 13 embedded in the trenches 25. The interlayer insulating film 14 contains NSG or BPSG. Contact holes are opened in the interlayer insulating film 14, and source electrodes 18 in contact with the n⁺⁺-type source regions 7 and the p⁺⁺-type contact regions 6 are provided at bottoms of the contact holes. The source electrodes 18 are in contact with the n⁺⁺-type source regions 7 and the p⁺⁺-type contact regions 6. The source electrodes 18 are electrically insulated from the gate electrodes 13 by the interlayer insulating film 14. A source electrode pad (main electrode) 16 containing an Al—Si film is disposed on the source electrodes 18. The Al—Si film may be an Al—Si alloy. For example, a barrier metal 15 may be provided between the source electrodes 18 and the interlayer insulating film 14 to prevent diffusion of metal atoms from the source electrodes 18 to the gate electrodes 13.

A plating film 20 is selectively disposed on an upper part of the source electrode pad 16, and solder (not depicted) is selectively disposed on a surface of the plating film 20. The plating film 20 is, for example, a nickel (Ni) plating film. The solder is provided with a pin-shaped electrode (not depicted) which is a wiring material for pulling out electric potential of the source electrodes 18 to the outside. The pin-shaped electrode has a needle-like shape and is joined to the source electrode pad 16 in an upright state. In FIG. 1, while only two MOS gate (insulating gate consists of metal-oxide film-semiconductor) structures are depicted in the active region 50, more MOS gate structures may be arranged in parallel.

In the embodiment, as described later, an Al—Si film 16 is deposited while maintaining a wafer temperature at 350 degrees C. or more and 480 degrees C. or less in a sputtering process. Thus, an area where Al orientation in the Al—Si film 16 is (111) occupies 99% or more. An average particle diameter of Al—Si particles in the formed Al—Si film 16 is 5.5 μm or more but not more than 10 μm, and preferably, may be 6 μm or more but not more than 8 μm.

As described, by making the area of the Al orientation (111) of the Al—Si film 16 a certain value or more, generation of abnormal etch pits during plating pre-treatment can be suppressed to prevent connection of etch pits in a sputtered aluminum film after plating deposition. Thus, mechanical strength after chip assembly can be improved to ensure product reliability. While the Al—Si film 16 has been described as an example of the main electrode, an Al film or an Al—Si—Cu film may be the example. The Al—Si—Cu film may be an Al—Si—Cu alloy. The Al contained in the main electrode may be, in at least a part of the region, 90 wt % or more, 95 wt % or more, or 97 wt % or more.

Next, a method of manufacturing the silicon carbide semiconductor device according to the embodiment is described. FIG. 2 is a flowchart of the method of manufacturing the silicon carbide semiconductor device according to the embodiment. First, a semiconductor element structure is formed as follows (step S1). The n⁻-type drift region 2 is epitaxially grown on a front surface of the n⁺-type silicon carbide substrate 1.

Then, the p-type base region 5 is epitaxially grown on a front surface of the n⁻-type drift region 2. The p-type base region 5 may be formed by ion implantation. An n⁻-type high concentration region may be formed between the n⁻-type drift region 2 and the p-type base region 5.

Thereafter, the p-type regions (the p⁺-type partial regions 4, the p⁺⁺-type contact regions 6, the p⁺-type regions 26) are formed by photolithography and ion implantation of a p-type dopant, and the n⁺⁺-type source regions 7 are formed by photolithography and ion implantation of an n-type dopant. Then, a heat treatment is performed to activate the dopants ion-implanted into the n⁻-type drift region 2 and the p-type base region 5. This heat treatment for activating the dopants may be performed each time the dopants are ion-implanted, or may be performed once collectively for the dopants. Next, the trenches 25, the gate insulating films 11, and the gate electrodes 13 are formed by a general method.

Thereafter, the interlayer insulating film 14 is formed on the p-type base region 5, the p⁺⁺-type contact regions 6, and the n⁺⁺-type source regions 7, the contact holes are formed in the interlayer insulating film 14, and the source electrodes 18 is formed in the contact holes (step S2).

Next, a Ti film is uniformly deposited in the contact holes and on the surface of the interlayer insulating film 14 by a sputtering method. Next, a TiN film is deposited on the surface of the Ti film by a sputtering method. As described, the barrier metal 15 is stacked on the interlayer insulating film 14 and is provided in the contact holes. Thereafter, the Ti film on the bottom of the contact hole is silicified by the heat treatment (annealing).

Next, the Al—Si film to be the source electrode pad 16 is deposited by, for example, a sputtering method (step S3). The Al—Si film is, for example, aluminum (Al—Si) containing silicon at a rate of 1%. The source electrode pad 16 may be formed by an Al metal film other than the Al film or the Al—Si film. Next, the Al—Si film is patterned to form the source electrode pad 16.

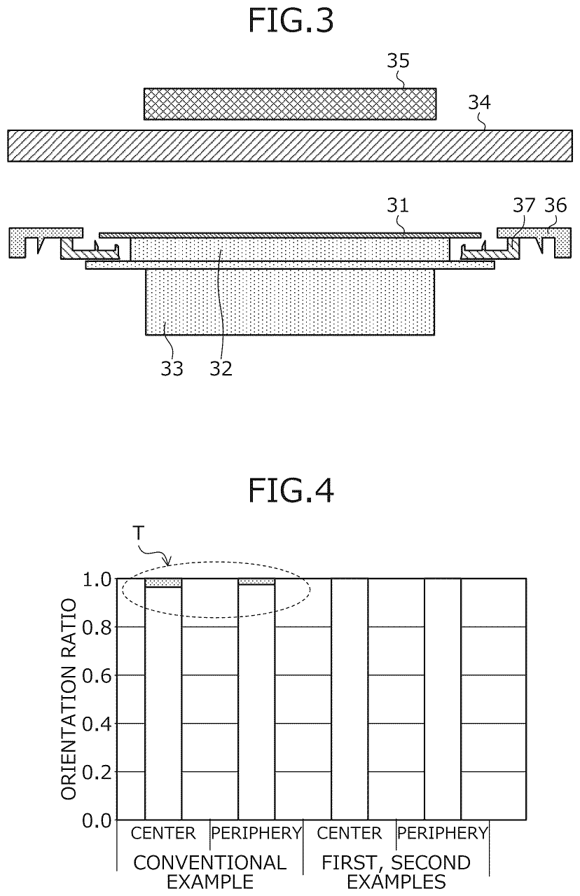

FIG. 3 is a cross-sectional view depicting sputtering of the Al—Si film of the silicon carbide semiconductor device according to the embodiment. The Al—Si film is formed by the sputtering method. In the sputtering method, a SiC wafer 31 is transported onto a stage 32 using a wafer transport ring 37 in a vacuum chamber (not depicted) and is fixed by a cover ring 36, an inert gas such as argon is injected into the vacuum chamber, a high voltage is applied to the inert gas to generate plasma, whereby argon ions or the like are caused to collide with a target 34, and atoms of a material of the target 34 fly out in reaction to the collision and adhere to the SiC wafer 31, resulting in depositing the Al—Si film. In magnetron sputtering in FIG. 3, a source magnet 35 is installed on a back of the target 34 and generates a magnetic field around the target 34. Since the magnetic field captures electrons, an electron concentration in the magnetic field increases thereby increasing the electron concentration near the target 34 and improving efficiency of sputtering.

Here, the results of measuring an orientation ratio of the Al—Si film by changing sputtering conditions are depicted. FIG. 4 is a graph depicting the orientation ratio of the Al—Si film in a conventional example and examples. In FIG. 4, the orientation ratio indicates a proportion of misorientation from a (111) direction. In the conventional example, a temperature of an electrostatic chuck 33 was set to 300 degrees C., the electrostatic chuck 33 itself was turned on, and the wafer temperature during deposition was set to less than 350 degrees C. When turned on, the electrostatic chuck 33 holds the SiC wafer 31 onto the stage 32 by suction and has a function of preventing a temperature of the SiC wafer 31 from rising too much above a certain level. In a first example of the examples, a temperature of the electrostatic chuck 33 is set to 160 degrees C., the electrostatic chuck 33 itself is turned off, and the wafer temperature during deposition was set to 350 degrees C. or more. In a second example, the temperature of the electrostatic chuck 33 is set to 250 degrees C., the electrostatic chuck 33 itself is turned off, and the wafer temperature during deposition is set to 350 degrees C. or more.

As depicted in FIG. 4, in the conventional example, the orientation ratio of the Al—Si film in the region T in FIG. 4 is less than 99% even at a center and a periphery, but in the first and second examples, the orientation ratio of the Al—Si film is 99% or more and is almost 100% even at the center and the periphery. Thus, by turning off the electrostatic chuck 33 to stop the function of preventing the temperature of the electrostatic chuck 33 from rising too much above a certain level and thereby setting the wafer temperature during deposition to 350 degrees C. or higher, the area in which the Al orientation of the Al—Si film is (111) can be 99% or more. The wafer temperature during deposition is preferably 480 degrees C. or less.

By increasing a temperature of the stage 32, the wafer temperature during deposition can be set to 350 degrees C. or more even when the electrostatic chuck 33 is turned on. Even in this case, the area of the Al—Si film where the Al orientation is (111) can be 99% or more.

A result of analyzing the Al—Si film created in the first and second examples by electron backscatter diffraction (EBSD) revealed that an average particle diameter of the Al—Si particles in the Al—Si film was 6 μm or more but not more than 8 μm. Here, while a case where the Al—Si film is used as the source electrode pad 16 is depicted, the same applies in a case of the Al film or other Al alloy film.

Next, the surface of the Al—Si film is pre-treated for plating in an etching bath or a zincate treatment bath (step S4). Thereafter, a plating film 20 is formed on the sputtered Al—Si film by electroless Ni plating and Au plating (step S5). Thereafter, a gate pad (not depicted), a passivation film (not depicted), and the drain electrode 17 are formed by the general method. A portion of the source electrode pad 16 exposed in an opening of the passivation film becomes the source pad. Subsequently, the semiconductor wafer is diced (cut) into individual chips, whereby the silicon carbide semiconductor device 70 depicted in FIG. 1 is completed.

While etch pits growth can be suppressed by weakening the pre-treatment such as the zincate treatment, this case is not preferable because adhesion between the plating film 20 and the Al—Si film 16 is weakened. On the other hand, in the embodiment, the etch pit growth can be suppressed without weakening the adhesion.

As described above, according to the embodiment, the Al—Si film is deposited while maintaining the wafer temperature at 350 degrees C. or more but not more than 480 degrees C. during the sputtering, and the area of the deposition surface where the Al orientation of the Al—Si film is (111) is set to 99% or more. This enables suppression of the generation of abnormal etch pits during the plating pre-treatment to prevent the etch pits from becoming connected to each other in the Al—Si film after plating deposition. Thus, the mechanical strength after chip assembly can be improved to ensure the product reliability.

As described above, the present disclosure can be modified in various ways without departing from the spirit of the disclosure, and in the embodiments described above, for example, the dimensions and dopant concentrations of portions are set in various ways according to necessary specifications. While the first conductivity type is an n-type and the second conductivity type is a p-type in the embodiments, the present disclosure is similarly implemented when the first conductivity type is a p-type and the second conductivity type is an n-type.

According to the described disclosure, an area of an Al—Si film (Al alloy film) in which Al orientation is (111) occupies 99% or more. Thus, generation of abnormal etch pits during plating pre-treatment is suppressed thereby preventing connection of etch pits in the Al—Si film after plating deposition. Thus, mechanical strength after chip assembly can be improved to ensure product reliability.

The semiconductor device and the method of manufacturing a semiconductor device in the present disclosure achieve an effect in that the generation of abnormal etch pits can be suppressed and the mechanical strength after chip assembly is improved, ensuring product reliability.

As described above, the semiconductor device and the method of manufacturing a silicon carbide semiconductor device according to the present disclosure are useful for power semiconductor devices used in power converting equipment such as inverters, power supply devices for various industrial machines, igniters for automobiles, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device comprising:
a semiconductor substrate;
an element structure disposed on the semiconductor substrate; and
a main electrode disposed on the element structure, wherein
the main electrode is a film containing Al, in which an area having Al orientation of (111) occupies 99% or more of a total area of the film containing Al.

2. The semiconductor device according to claim 1, wherein the film containing Al has an average particle diameter of 5.5 μm or more but not more than 10 μm.

3. The semiconductor device according to claim 1, wherein the film containing Al is an Al film, an Al—Si film, or an Al—Si—Cu film.

4. A method of manufacturing a semiconductor device, the method comprising:
preparing a semiconductor substrate and forming an element structure on the semiconductor substrate; and
depositing a main electrode on the element structure, including
sputtering a film containing Al, with a wafer temperature during the deposition being 350 degrees C. or more but not more than 480 degrees C., to thereby form the main electrode.

5. The method of manufacturing a semiconductor device according to claim 4, wherein
an electrostatic chuck holds the semiconductor substrate onto a stage by suction, and
in the sputtering, the electrostatic chuck is turned off.
